(19) United States
(12) Patent Application Publication
(10) Pub. No.: US 2008/0299682 A1
(43) Pub. Date: Dec. 4, 2008

(54) METHOD FOR REMOVING POLY SILICON

(75) Inventor: Jong Won SUN, Gokseong-gun (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 12/133,130

(22) Filed: Jun. 4, 2008

(30) Foreign Application Priority Data
Jun. 4, 2007 (KR) 10-2007-0054580

(51) Int. Cl. H01L 21/66

(52) U.S. Cl. 438/8; 257/E21.53

(57) ABSTRACT

Methods for removing poly silicon. In one example embodiment, a method for removing poly silicon that is formed on a silicon wafer includes the steps of growing the poly silicon as a silicon oxide through a thermal oxidation process and removing the silicon oxide using an etching solution.

### CROSS-REFERENCE TO A RELATED APPLICATION

This application claims the benefit of Korean Patent Application No. 10-2007-0054580, filed on 4 Jun., 2007 which is hereby incorporated by reference as if fully set forth herein.

### BACKGROUND

1. Field of the Invention

The present invention relates to methods for removing poly silicon. More particularly, the present invention relates to methods for growing poly silicon on a silicon wafer as silicon oxide SiO₂ through a thermal oxidation process and then removing the poly silicon with an etching solution.

2. Description of the Related Art

A semiconductor transistor can be formed by depositing a poly silicon film on a silicon wafer using low pressure chemical vapor deposition (LPCVD). LPCVD is a method for forming a single crystal semiconductor film or insulating film using a chemical reaction. Poly silicon is generally deposited on a bare silicon wafer in order to monitor particles and foreign substances generated during the deposition process. A bare wafer that is used once can not generally be reused for the same purpose. Instead, the poly silicon is stripped from the wafer using an HNO₃ solution in order to be recycled as dummy wafer.

FIG. 1 is a process flow chart showing a prior art method for removing poly silicon. The method of FIG. 1 first performs a poly silicon deposition test process (S102). At S102, LPCVD of poly silicon is performed on a bare silicon wafer and the generation of particles and foreign substances is monitored during the LPCVD. At S102, the poly silicon may be deposited, for example, at a thickness of 2500 Å.

The method of FIG. 1 next performs a removing process (S104). At S104, the poly silicon is removed using an HNO₃ etching solution. The removal time may be, for example, 80 sec.

The method of FIG. 1 then performs a cleaning process (S106). At S106, micro residues generated during the deposition and removing of the poly silicon are cleaned using a cleaning solution. In some example embodiments, the cleaning solution has a volume ratio of about 1:99 of Hydrogen Fluoride (HF) and De-Ionized Water (DI). In some example embodiments, the cleaning solution is an organic solvent or a dilute HF.

The method of FIG. 1 next performs a thickness measurement and a light projector examination process (S108). At S108, the thickness of the wafer from which the poly silicon has been removed is measured and the wafer is examined using a light projector to determine: 1) whether a step exists on a surface of the wafer due to the removal of the poly silicon, 2) whether any poly silicon film remains on the wafer, or 3) whether the wafer is not over etched up to edge portions thereof.

The method of FIG. 1 next injects the wafer into another process as a dummy wafer (S110) if the wafer is judged to be recyclable to another process during the thickness measurement and light projector examination process during S108. Unfortunately, however, the wafer is often judged not to be recyclable to another process due to poly silicon film remaining on the surface of the wafer, which results in a peeling phenomenon due to heat when is used as a dummy wafer in another process. Further, the wafer is often judged not to be recyclable to another process due to the wafer being over etched up to the edge portions of the wafer, which can result in breakage of the silicon wafer. Both conditions make recycling the wafer to subsequent processes unstable.

FIGS. 2A and 2B are photographs of a surface shape of a silicon wafer after removing poly silicon using the prior art method of FIG. 1. In particular, FIG. 2A shows particles generated due to a peeling phenomenon during the removing process of the poly silicon, and FIG. 2B shows a silicon wafer that is over etched up to an edge portion thereof. As disclosed in the photograph of FIG. 2A, the plurality of dots represents residue particles of the poly silicon. As disclosed in the photograph of FIG. 2B, the boundary between a black portion that is a dark room and a white portion that is a wafer is not flat but is over etched.

### SUMMARY OF EXAMPLE EMBODIMENTS

In general, example embodiments of the invention relate to a method for removing poly silicon. The example methods disclosed herein remove residue particles of the poly silicon and reduce over etching on the surface of the silicon wafer. In addition, the example method of FIG. 3A can make up for the weaknesses of the prior art method for removing poly silicon by minimizing damage to the wafer, resulting in reduced costs and enabling the recycling of a wafer as a dummy wafer in other processes.

In one example embodiment, a method for removing poly silicon that is formed on a silicon wafer includes the steps of growing the poly silicon as a silicon oxide through a thermal oxidation process and removing the silicon oxide using an etching solution.

In another example embodiment, a method for removing poly silicon that is formed on a silicon wafer includes various steps. First, the poly silicon is grown as a silicon oxide through a thermal oxidation process. Next, the silicon oxide is removed using an etching solution. Then, the wafer is subjected to a cleaning process. Next, a thickness of the wafer is measured and the wafer is examined using a light projector. Finally, the wafer is recycled to another process.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of example embodiments of the invention and are incorporated in and constitute a part of this application, illustrate example embodiments of the invention. In the drawings:

FIG. 1 discloses a prior art method for removing poly silicon;

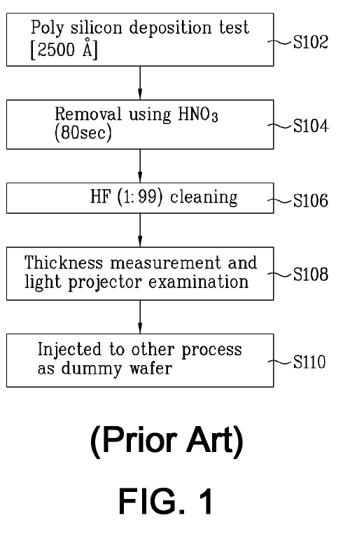

FIGS. 2A and 2B are photographs of a surface shape of a silicon wafer after the prior art method of FIG. 1 is performed thereon;

FIG. 3A discloses aspects of an example method for removing poly silicon;

FIG. 3B discloses the formation of silicon oxide due to an example thermal oxidation process; and

FIGS. 4A to 4C are photographs of cross-sectional and surface shapes of silicon wafers after the example method of FIG. 3A is performed thereon.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

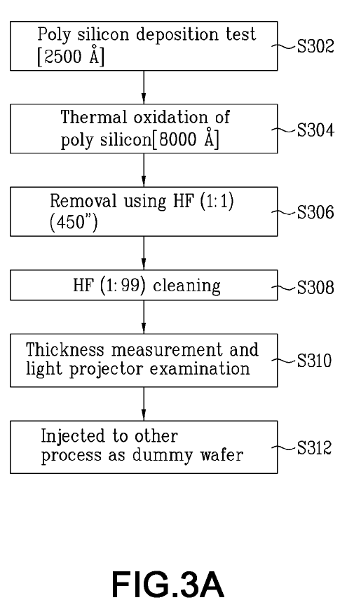

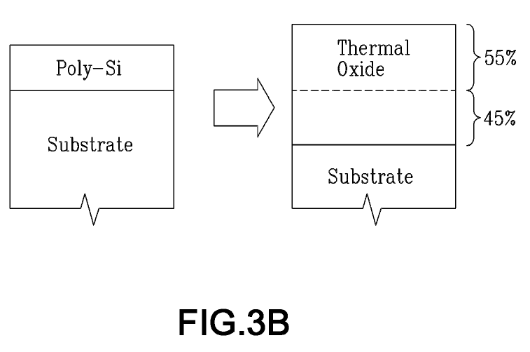

FIG. 3A discloses aspects of an example method for removing poly silicon. The method of FIG. 3A deposits poly silicon on a silicon wafer and then uses a thermal oxidation process to remove a silicon oxide using an HF solution. The silicon wafer may then be recycled and reused by another process.

The method of FIG. 3A first performs a poly silicon deposition test (S302). At S302, LPCVD of poly silicon on a bare silicon wafer. At S302, particles and foreign substances generated during the deposition process are monitored. As defects resulting from particles can decrease the yield in large-scale integration, the monitoring of particles and foreign substances at S302 can increase yield. In one example embodiment, the thickness of the poly silicon that is deposited on the silicon wafer at S302 is about 2500 Å.

The method of FIG. 3A next performs thermal oxidation of the poly silicon (S304). In FIG. 3B, the diagram on the left shows the poly silicon formed on the silicon wafer prior to the thermal oxidation of the poly silicon at S304, and the diagram on the right shows the poly silicon and a portion of the poly wafer proximate the poly silicon grown as a silicon oxide after the thermal oxidation of the poly silicon at S304. Therefore, at S304, silicon oxide is formed both above and beneath the original surface of the silicon wafer. In one example embodiment, between about 45% and about 55% of the thickness of the silicon oxide exists above the original surface of the silicon wafer and between about 55% and about 45% of the thickness of the silicon oxide exists below the original surface of the silicon wafer, as shown in the right hand column of FIG. 3B. In one example embodiment, the thickness of the silicon oxide generated through the thermal oxidation process S304 is about 8000 Å.

The thermal oxidation process S304 may be a process reacting oxygen or steam with a surface of a wafer to form thin and uniform silicon oxide SiO2, wherein the oxide is grown on a general silicon wafer and such a process is referred to as a thermal oxide formation. The thermal oxidation process is performed at a temperature between about 800° C. and about 1200° C.

The method of FIG. 3A next performs removal of the grown silicon oxide (S306). In one example embodiment, at S306, the grown silicon oxide is removed using an HF solution having volume ratio of about 1:1 of HF and DI. In on example embodiment, the removal time thereof is between about 300 sec and about 450 sec. In some example embodiments, the HF solution may have a volume ratio between about 1:1 and 1:5 of HF and DI. Although the removal time is reduced as the volume ratio of the HF in the HF solution rises, a proper compromise should be found in view of process stability and costs.

As described above, the reason why the silicon oxide is removed using the HF solution having volume ration of about 1:1 of HF and DI in one example embodiment is that since the HF solution has chemical characteristics to clearly remove oxide but not to clearly remove silicon oxide, over etching and breakage of the silicon wafer can be reduced, making it possible to avoid generation of various particles.

The method of FIG. 3A next performs s cleaning process (S308). At S308, micro residues generated in the previous step are cleaned using cleaning solution having a volume ratio between about 1:99 and about 1:95 of HF and DI. As various by-products may remain on the surface of the wafer steps S302, S304, and S306, as such by-products can cause reliability problems in the wafer when the wafer is recycled for use in subsequent processes, the cleaning performed as S308 can improve reliability of the wafer when the wafer is recycled for use in subsequent processes.

The method of FIG. 3A next performs a thickness measurement and a light projector examination (S310). At S310, the thickness of the wafer is measured and the wafer is examined using a light projector to determine: 1) whether a step exists on a surface of the wafer due to the removal of the poly silicon, 2) whether any poly silicon film remains on the wafer, or 3) whether the wafer is not over etched up to edge portions thereof.

The method of FIG. 3A next injects the wafer into another process as a dummy wafer (S312). At S312 when the wafer is judged to be recyclable to another process during the thickness measurement and light projector examination process of S310, the wafer is injected into another process as a dummy wafer.

Methods for manufacturing semiconductor memory devices and semiconductor non-memory devices may further include a process for stacking an insulating layer, a dielectric layer, and a metal layer, among other layers on a substrate such as a wafer made of single crystal silicon and a process for forming the stacked film in a desired shaped pattern.

In order to examine whether the films are stacked at an originally desired thickness, the thickness of the films may be measured by non-destructive film thickness measurement equipment having high accuracy right after completing the stacking of the films. Film thickness measurement equipment can generally be divided into non-destructive film thickness measurement equipment and destructive film thickness measurement equipment. Non-destructive film thickness measurement equipment may use an ellipsometer or thickness measurement equipment that employs laser or light absorption and reflectivity of a lamp, including, but not limited to, Nanospec, Optiprobe, and/or Metapulse.

Manufacturing semiconductor wafers generally includes the use of a light projector for examining foreign substances existing in the wafer with the naked eye. When examining the wafer, the target wafer may be held with tweezers in a state where a lamp is turned on and light is shined to the inside of a box body through a light inlet hole. Then the wafer is injected into the inside of the box body to be examined with the naked eye to determine whether foreign substances have attached to the wafer. The foreign substances inside of the box body may be discharged through a discharge line.

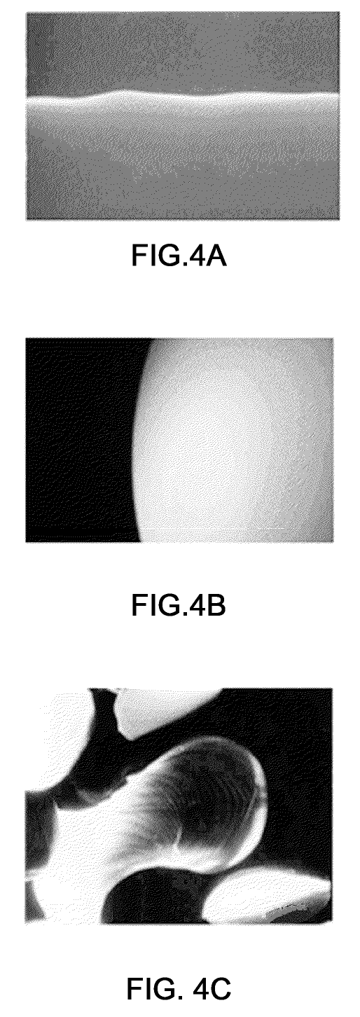

FIGS. 4A to 4C are photographs of cross-sectional and surface shapes of silicon wafers after the example method of FIG. 3A is performed thereon. FIGS. 4A to 4C shows a reduction in the step of the surface of the wafers and a reduction in the over etching of the edge portion of the wafers.

As disclosed in FIG. 4A, the method of FIG. 3A results in the step of the cross-section of the silicon wafer being reduced after the poly silicon is removed.

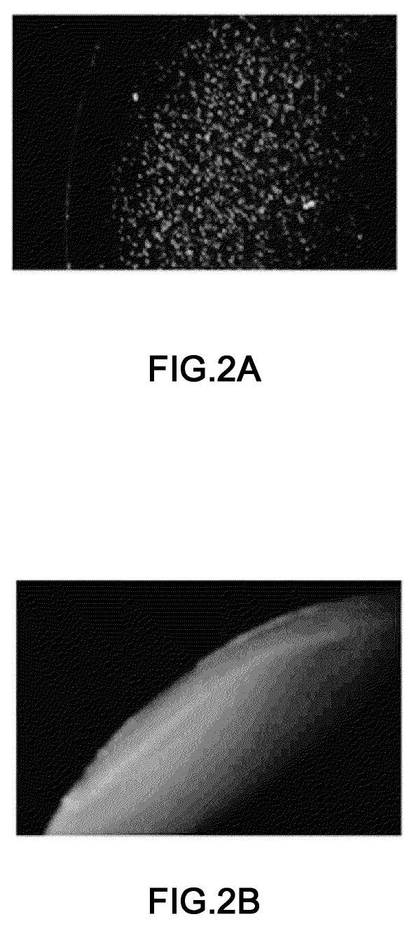

As disclosed in FIG. 4B, the method of FIG. 3A results in the edge portion of the wafer not being over etched to have a regular shape as compared to the photograph in FIG. 2B.

As disclosed in FIG. 4C, the surface of the silicon wafer after the poly silicon is removed is shown using scanning electron microcopy (SEM) equipment. In the photograph in FIG. 4C, there are somewhat dug spots on the crystal surface of the silicon wafer when confirming the SEM. This is the reason that the crystal direction of the crystal of the silicon is etched in sequence of <1 1 1>, <1 1 2>, <1 1 3>, <1 1 5> and <1 1 7> by the HF solution during the removing process S306 using the HF (1:1). However, it is demonstrated that this feature does not largely affect the silicon safer, wherein it is disclosed on ‘Superlattices and Microstructures’ written by G. Wsiz, 2004, No. 37, pages 353-358, which is incorporated herein by reference in its entirety.

As described above, the example method for removing poly silicon of FIG. 3A grows the poly silicon deposited on a silicon wafer as a silicon oxide through a thermal oxidation process and removes the silicon oxide using an HF solution. The example method of FIG. 3A removes residue particle of the poly silicon and reduces over etching on the surface of the silicon wafer. In addition, the example method of FIG. 3A can make up for the weaknesses of the prior art method for removing poly silicon by minimizing damage to the wafer, resulting in reduced costs and enabling the recycling of a bare wafer as a dummy wafer in other processes.

Although example embodiments of the present invention have been shown and described, changes might be made in these example embodiments. The scope of the invention is therefore defined in the following claims and their equivalents.

What is claimed is:

1. A method for removing poly silicon that is formed on a silicon wafer, the method including the steps of:
growing the poly silicon as a silicon oxide through a thermal oxidation process; and
removing the silicon oxide using an etching solution.

2. The method according to claim 1, wherein the etching solution is an HF solution having volume ratio between about 1:1 and about 1:5 of HF and DI.

3. The method according to claim 1, wherein between about 45% and about 55% of the thickness of the silicon oxide exists above an original surface of the silicon wafer and between about 55% and about 45% of the thickness of the silicon oxide exists below the original surface of the silicon wafer.

4. The method according to claim 1, wherein the silicon wafer is a bare wafer.

5. The method according to claim 4, further comprising recycling the bare wafer to another process after the poly silicon is removed.

6. The method according to claim 1, further comprising subjecting the wafer to a cleaning process after removing the silicon oxide from the wafer using the etching solution.

7. The method according to claim 6, wherein the cleaning solution used in the cleaning process is an HF solution having a volume ratio between about 1:99 and about 1:95 of HF and DI.

8. The method according to claim 6, wherein the cleaning solution used in the cleaning process is an organic solvent or a dilute HF.

9. The method according to claim 1, wherein the thermal oxidation process is performed at a temperature between about 800° C. and about 1200° C.

10. The method according to claim 1, further comprising, after removing the silicon oxide using the etching solution:
measuring a thickness of the silicon wafer and examining the wafer using a light projector; and
recycling the silicon wafer to another process.

11. The method according to claim 10, wherein the thickness measurement of the silicon wafer is made using non-destructive film thickness measurement equipment.

12. The method according to claim 1, wherein the removal time of the silicon oxide using the etching solution is between about 300 sec and about 450 sec.

13. A method for removing poly silicon that is formed on a silicon wafer, the method including the steps of:
growing the poly silicon as a silicon oxide through a thermal oxidation process;
removing the silicon oxide using an etching solution;
subjecting the wafer to a cleaning process;
measuring a thickness of the silicon wafer and examining the wafer using a light projector; and
recycling the silicon wafer to another process.

14. The method according to claim 13, wherein the etching solution is an HF solution having volume ratio between about 1:1 and about 1:5 of HF and DI.

15. The method according to claim 13, wherein between about 45% and about 55% of the thickness of the silicon oxide exists above an original surface of the silicon wafer and between about 55% and about 45% of the thickness of the silicon oxide exists below the original surface of the silicon wafer.

16. The method according to claim 13, wherein the silicon wafer is a bare wafer.

17. The method according to claim 13, wherein the cleaning solution used in the cleaning process is an HF solution having a volume ratio between about 1:99 and about 1:95 of HF and DI.

18. The method according to claim 13, wherein the cleaning solution used in the cleaning process is an organic solvent or a dilute HF.

19. The method according to claim 13, wherein the thermal oxidation process is performed at a temperature between about 800° C. and about 1200° C.

20. The method according to claim 13, wherein the removal time of the silicon oxide using the etching solution is between about 300 sec and about 450 sec.
